(19) United States
(12) Patent Application Publication
(10) Pub. No.: US 2024/0186440 A1
(43) Pub. Date: Jun. 6, 2024

(54) DEVICE

(71) Applicant: Sumitomo Chemical Co., Ltd., Tokyo (JP)

(72) Inventor: Nir Yaacobi-Gross, Godmanchester (GB)

(73) Assignee: Sumitomo Chemical Co., Ltd., Tokyo (JP)

(21) Appl. No.: 18/501,017

(22) Filed: Nov. 2, 2023

(30) Foreign Application Priority Data
Nov. 3, 2022 (GB) 2216386.9

(51) Int. Cl. H01L 31/107; H01L 31/0352

(52) U.S. Cl. CPC H01L 31/107; H01L 31/035218; H01L 2031/0344

(57) ABSTRACT

A short-wave near infrared, SWIR, photodetector (13) for wavelengths exceeding 900 nm is described. The SWIR photodetector (13) includes a silicon single-electron bipolar avalanche transistor, SEBAT (1), having an emitter (3), a base (4) and a collector (5). The SEBAT (1) is formed using CMOS compatible materials and processes. The SWIR photodetector (13) also includes a thin-film photodiode (12) formed directly on the SEBAT and configured such that, if the SEBAT (1) is NPN, a cathode (14) of the photodiode (12) directly contacts the emitter (3), or if the SEBAT (1) is PNP, an anode (15) of the photodiode (12) directly contacts the emitter (3).

### BACKGROUND

Single photon detectors are important building blocks for a variety of applications. For example, in ranging systems based on Time-of-flight such as Light Detection and Ranging (LiDAR). Internal signal amplification is usually needed in such components in order to generate macroscopic measurable signals.

Single-photon avalanche diodes (SPADs) may be used for single (or low number) photon detection. Silicon based SPADs lose sensitivity in the near infrared (NIR) and short-wave infrared (SWIR) due to the photon energy approaching, and then dropping below, the silicon band-gap of 1.12 eV. The SWIR wavelengths are of particular interest for LiDAR applications due to the requirements for wavelengths which are safe for the eyes of bystanders/operators. The SWIR wavelength range also includes spectral bands in which little or no solar light reaches earth's surface, which may help to minimise the undesirable effects of outdoor ambient light. SPADs formed using other inorganic semiconductor systems have been proposed. However, these are often more complex, may require rare earth elements (which are expensive and vulnerable to supply disruptions) and/or require cooling below ambient temperatures to mitigate otherwise excessive dark currents. SPADs formed using other inorganic semiconductor systems may also require fabrication using processes and/or materials which are incompatible with silicon CMOS processes, making it harder to cost-effectively integrate such single-photon detectors with other circuit components such as amplifiers, quenching circuits and so forth.

Villa, F.; Severini, F.; Madonini, F.; Zappa, F. “SPADs and SiPMs Arrays for Long-Range High-Speed Light Detection and Ranging (LiDAR)”, Sensors 2021, 21, 3839. https://doi.org/10.3390/s21113839 provides a review of sensor technologies for LiDAR applications.

Integration of organic photodiodes with silicon CMOS components and processes has been proposed, see Lai-Hung Lai, Chin-Chuan Hsieh, Jhao-Lin Wu, and Yi-Ming Chang, “Organic Photodiode Integration on Si Substrates beyond 1000 nm Wavelength”, ACS Applied Electronic Materials 2022 4 (1), 168-176, DOI: 10.1021/acsaelm.1c00915. See also Shekhar, H., Fenigstein, A., Leitner, T. et al. “Hybrid image sensor of small molecule organic photodiode on CMOS—Integration and characterization”, Sci Rep 10, 7594 (2020). https://doi.org/10.1038/s41598-020-64565-5.

Lany et al, described the concept of a single electron bipolar avalanche transistor (SEBAT), see “Electron counting at temperature in an avalanche bipolar transistor” Applied Physics Letters 92, 022111 2008. Webster et al, demonstrated SEBAT fabrication in a modern CMOS process, see “A single electron bipolar avalanche transistor implemented in 90 nm CMOS” Solid-State Electronics 76, 2012, 116-118.

US 2019/0131467 A1 describes connecting a germanium photodiode in parallel with the emitter of a single electron bipolar avalanche transistor (SEBAT). US 2020/0212245 A1 describes a bipolar transistor configured for operation at a collector-to-base voltage above the breakdown voltage, with emitter, base and collector, a current or voltage source electrically connected with the emitter, and a quenching component electrically connected with the collector.

### SUMMARY

In a first aspect, the present disclosure provides a short-wave near infrared, SWIR, photodetector for wavelengths exceeding 900 nm. The SWIR photodetector includes a silicon single-electron bipolar avalanche transistor, SEBAT, having an emitter, a base and a collector. The SEBAT is formed using CMOS compatible materials and processes. The SWIR photodetector also includes a thin-film photodiode formed directly on the SEBAT and configured such that, if the SEBAT is NPN, a cathode of the photodiode directly contacts the emitter, or if the SEBAT is PNP, an anode of the photodiode directly contacts the emitter.

Thin-film may mean that a light absorbing (alternatively “photoactive”) layer of the photodiode does not exceed a thickness of 1000 nm. Thin-film may refer to the photodiode being deposited using one, or a combination, of thin-film deposition processes including, but not limited to, physical vapour deposition (PVD), chemical vapour deposition (CVD), solution processing such as spin coating or printing, molecular self-assembly, and so forth.

The thin-film photodiode may be fabricated using materials and processes which are capable of integration with CMOS processes.

The anode or cathode contacting the emitter may include, or take the form of, a CMOS compatible metal. CMOS compatible metals may include one or more selected from aluminium Al, tungsten W, titanium nitride TiN, aluminium-titanium nitride AlTiN, and alloys thereof. The anode or cathode contacting the emitter may include, or take the form of, a conductive oxide. The conductive oxide may include, or take the form of, indium tin oxide ITO, indium zinc oxide IZO, or a blend thereof. The anode or cathode contacting the emitter may include, or take the form of, an organic conductor or semiconductor. The organic conductor or semiconductor may include, or take the form of, small molecules, polymers, or a blend.

The anode or cathode contacting the emitter may take the form of a multilayer. The multilayer may include a first CMOS compatible metal layer contacting the emitter. The multilayer may include one or more intermediate layers supported on the CMOS compatible metal layer. CMOS compatible metals may include one or more selected from aluminium Al, tungsten W, copper Cu, chromium Cr, titanium Ti, titanium nitride TiN, aluminium-titanium nitride AlTiN, tantalum Ta, and alloys thereof and metal silicides such as WSi₂. TiSi₂, CoSi₂, MoSi₂, TaSi₂. Each intermediate layer may be conductive or may be semiconductive.

The one or more intermediate layers may include, or take the form of, a second, different CMOS compatible metal.

The one or more intermediate layers may include, or take the form of, a conductive oxide. The conductive oxide may include, or take the form of, indium tin oxide ITO, indium zinc oxide IZO, aluminum doped zinc oxide (AZO), indium gallium zinc oxide (IGZO), or a blend thereof.

The one or more intermediate layers may include, or take the form of, an organic conductor or an organic semiconductor. The organic conductor or semiconductor may include, or take the form of, small molecules, polymers, or a blend. The organic conductor or semiconductor may include, or take the form of poly(3,4-ethylenedioxythiophene) polystyrene sulfonate (PEDOT:PSS).

The one or more intermediate layers may include, or take the form of, an organic or inorganic workfunction modification layer. The workfunction modification layer may include, or take the form of, polyethyleneimine (PEI) or ethoxylated polyethyleneimine (PETE), and so forth.

An insulating layer may overlie the SEBAT. The anode or cathode contacting the emitter may extend through a via in the insulating layer.

The SWIR photodetector may also include a quenching circuit for the SEBAT. The SWIT photodetector may also include an amplifier coupled to the collector and configured to convert output current spikes to digital pulses.

The quenching circuit may be passive. The quenching circuit may be active. The SEBAT may be configured for passive quenching, passive reset operation. The SEBAT may be configured for passive quenching, active reset operation. The SEBAT may be configured for active quenching, active reset. The terms “passive quenching”, “active quenching”, “passive reset” and “active reset” have the same meanings known in relation to single photon avalanche diodes, SPADs.

The quenching circuit and/or the amplifier may be integrally formed on the same substrate as the SEBAT.

The photodiode may be configured for zero-bias operation. Additionally or alternatively, the photodiode may be configured for reverse-bias operation. The configuration of the photodiode for reverse-bias operation may include, or take the form of, including contacts enabling application of a reverse-bias to the photodiode.

The reverse bias may preferably be low. A low reverse bias may be a bias less than a breakdown voltage of the photodiode. A low reverse bias may be less than or equal to 5.5 V, less than or equal to 5 V, less than or equal to 3.3 V, or less than or equal to 3 V. A low reverse bias may be calibrated to correspond to a dark-current of the photodiode remaining below a dark-current threshold. The dark-current threshold may be a current density of 1 μA·cm⁻² (the relevant area being the area of the photodiode junction).

The sensitivity of the photodiode may have a peak at a wavelength greater than or equal to 1100 nm. The peak may be between 1100 and 1600 nm. The peak may be at a wavelength greater than or equal to 1400 nm. The peak may be between 890 and 920 nm. The peak may be 905 nm. The peak may be between 1540 and 1560 nm. The peak may be 1550 nm.

The photoactive layer of the photodiode may include quantum dots. Quantum dots may include, or take the form of colloidal nano-crystals.

The photoactive layer of the photodiode may include, or take the form of, a perovskite material. The perovskite material may include, or take the form of CH₃NH3PbI₃₋ₓClₓ.

The photoactive layer of the photodiode may include, or take the form of, one or more organic semiconductors. The photoactive layer may include one or more small molecule organic semiconductors. The photoactive layer may include one or more polymer semiconductors.

The photoactive layer of the photodiode does not include Germanium (Ge). The photoactive layer of the photodiode may only include Germanium (Ge) as an impurity in trace quantities.

A SWIR photodetector array may include a number of SWIR photodetectors according to the first aspect, arranged in an array.

In the SWIR photodetector array, one or more layers of the photodiode other than the anode or cathode contacting the emitter may be uniform and extend across the array. In other words, the photoactive layer and/or counter electrode may be uniform, continuous layers overlying the array of SEBATs. Any intermediate layers may also be uniform, continuous layers co-extensive with the photoactive layer. The anode or cathode (respectively) that contacts the emitters may be patterned, with a separate anode or cathode (respectively) formed to directly contact the emitter of a respective SEBAT.

In the SWIR photodetector array, a separate photodiode may be formed to correspond to each emitter.

In the SWIR photodetector array, the array may be one-dimensional. In the SWIR photodetector array, the array may be two-dimensional.

A light detection and ranging, LIDAR, system may include the SWIR photodetector of the first aspect, or the SWIR photodetector array formed from a number of SWIR photodetectors of the first aspect.

In a second aspect, the present disclosure provides a method of fabricating a short-wave near infrared, SWIR, photodetector for wavelengths exceeding 900 nm. The method includes depositing a thin-film, vertical photodiode directly on a silicon single-electron bipolar avalanche transistor, SEBAT, having an emitter, a base and a collector. The SEBAT is formed using CMOS compatible materials and processes. If the SEBAT is NPN, a cathode of the photodiode is directly deposited on the emitter. Alternatively, if the SEBAT is PNP, an anode of the photodiode is directly deposited on the emitter.

The method may include features corresponding to any features of the SWIR photodetector and/or the SWIR photodetector array. Definitions applicable to the SWIR photodetector and/or the SWIR photo detector array may be equally applicable to the method.

### DESCRIPTION OF DRAWINGS

The disclosed technology and accompanying figures describe some implementations of the disclosed technology.

FIG. 1 illustrates a single electron bipolar avalanche transistor in schematic cross-section;

FIG. 2 illustrates a schematic plan view of the single electron bipolar avalanche transistor shown in FIG. 1;

FIG. 3 illustrates a first circuit for operating a single electron bipolar avalanche transistor;

FIG. 4A illustrates time variation of a collector-base voltage of a single electron bipolar avalanche transistor across several avalanche events;

FIG. 4B illustrates time variation of an output voltage corresponding to the plot shown in FIG. 4A;

FIG. 5 illustrates a second circuit for operating a near infrared photodetector;

FIG. 6 illustrates a near infrared detector in schematic cross-section;

FIG. 7 illustrates a first detector array in schematic cross-section; and

FIG. 8 illustrates a second detector array in schematic cross-section.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to a layer “over” another layer when used in this application means that the layers may be in direct contact or one or more intervening layers may be present. References to a layer “on” another layer when used in this application means that the layers are in direct contact. References to a specific atom include any isotope of that atom unless specifically stated otherwise.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

### Single Electron Bipolar Avalanche Transistor

The present invention concerns integrating thin-film photodiodes with single electron bipolar avalanche transistor (SEBAT) in single-photon detectors. Before describing embodiments of the present invention, it may be helpful to review the structure and operation of SEBATs with reference to an exemplary SEBAT device.

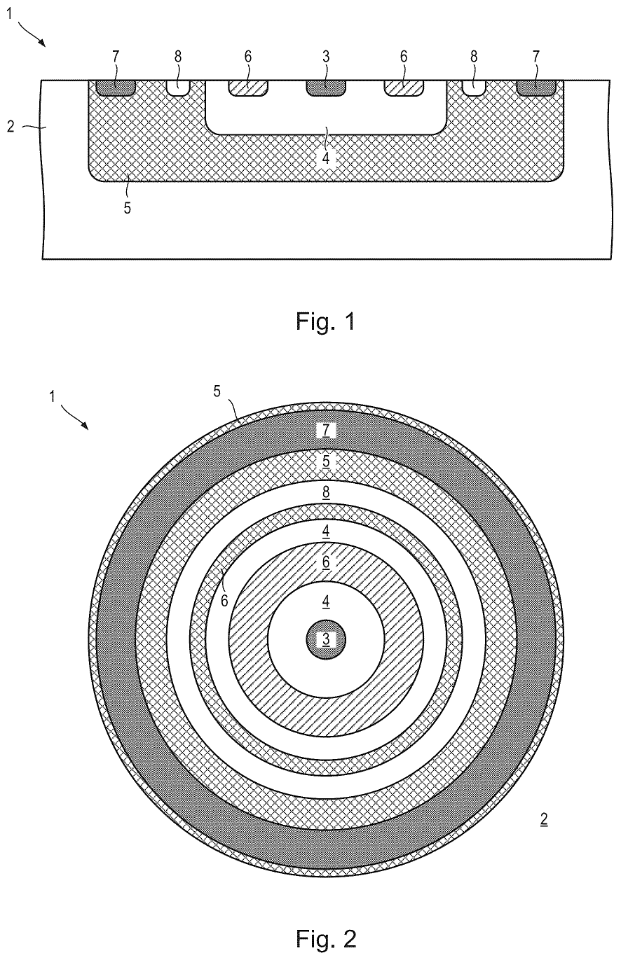

Referring to FIG. 1, an example of a single electron bipolar avalanche transistor 1 (SEBAT) is shown in a schematic cross-section.

Referring also to FIG. 2, the exemplary SEBAT 1 is shown in a schematic plan view.

The SEBAT 1 is formed on a semiconducting substrate 2. For the exemplary SEBAT 1, and for embodiments of the invention described hereinafter, the substrate 2 takes the form of a CMOS compatible substrate, such as, for example, silicon Si. The SEBAT 1 is a bipolar junction transistor, having an emitter 3, a base 4 and a collector 5. In the illustrated example, the emitter 3 is N+ doped, the base 4 is P doped and includes a P+ doped base contact region 6, and the collector 5 includes a N+ doped collector contact region 7 and a P doped guard ring 8. The substrate 2 may be P doped or intrinsic (undoped).

Referring in particular to FIG. 2, a concentric, circular configuration of the SEBAT 1 is preferred in order to avoid electric field concentrations from geometric effects when operating at high reverse bias to generate avalanche breakdowns (sometimes termed “Geiger mode”).

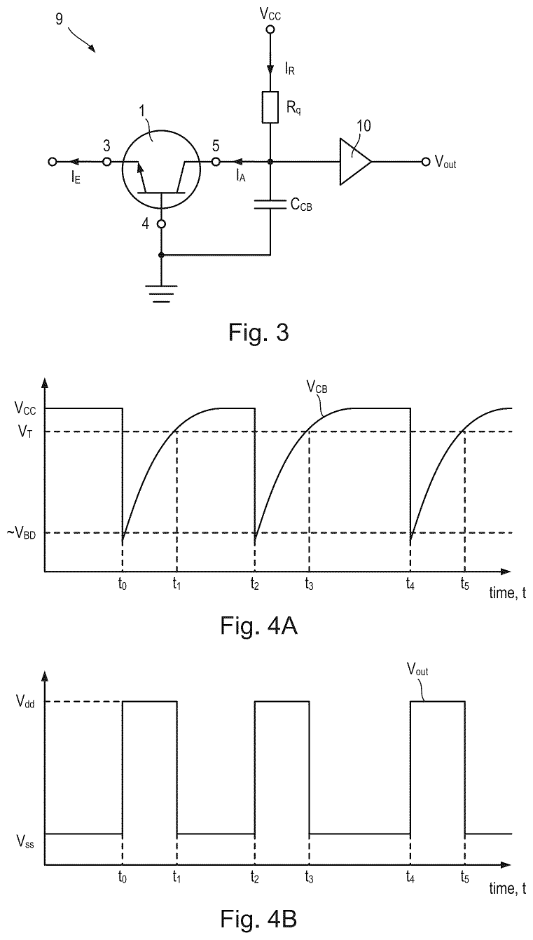

Referring also to FIG. 3, a circuit 9 configured for single electron detection using a SEBAT 1 is schematically shown.

The collector 5 is coupled to the input of an amplifier 10 and to a supply voltage V_{CC} via a quenching resistor R_{q}. A collector-base capacitance is indicated by capacitor C_{CB}. The base 4 is connected to system ground. A voltage or current source may be coupled to the emitter 3 to drive emitter current I_{E}. The basic circuit shown in FIG. 3 is similar to a conventional common-base amplifier circuit using a bipolar junction transistor. However, unlike other circuit applications of the bipolar junction transistor, the collector 5 supply voltage V_{CC}, of the SEBAT 1 exceeds the static collector-base breakdown voltage V BD (sometimes referred to as operating in the “Geiger mode”).

Referring also to FIGS. 4A and 4B, the operation of the circuit 9 shall be explained. FIG. 4A shows a schematic plot of collector-base voltage V_{CB} versus time. FIG. 4B shows a schematic plot of the amplifier 10 output Vₒᵤₜ versus time.

Initially, let the emitter current I_{E} of the SEBAT 1 be zero. If the leakage current of the collector-base junction is ignored, no current flows through the quenching resistor R_{q}. Consequently, V_{CB}∞V_{CC}, and the collector-base junction of the SEBAT is reverse biased by the supply voltage V_{CC}. As previously noted, the supply voltage V_{CC} in this instance exceeds the breakdown voltage V_{BD}, i.e. V_{CC}>V_{BD}. This situation is shown for times t<t₀ in FIGS. 4A and 4B. The amplifier output Vₒᵤₜ provides no signal.

If a negative voltage is applied to the emitter 3, the base-emitter junction is forward biased, and an emitter current I_{E} flows. Part of the emitter current I_{E} consists of emitter electrons that overcome the potential barrier between the emitter 3 and the base 4 and reach the collector-base junction. Once at the collector-base junction, any free electron will be accelerated by the strong electric field. Because the voltage V_{CC} applied on the collector-base junction is higher than its breakdown voltage V_{BD}, the electron is very likely to generate secondary electron-hole pairs by impact ionization. The other components of the emitter current I_{E}, namely, the hole current and the recombination current, are carried through the base 4 by holes and, therefore, cannot initiate an avalanche. The avalanche is self-sustaining above the breakdown voltage V_{BD}. In order to avoid the destruction of the SEBAT 1 and to allow for the detection of a subsequently injected electron, the avalanche current IA needs to be stopped.

This function is identical to the quenching of the avalanche current in a single-photon avalanche diode (SPAD). In the configuration shown in FIG. 3, the SEBAT 1 is biased through quench resistor R_{q} on the collector 5 side, forming what is sometimes termed as a “passive” quenching circuit. The value of the quench resistance R_{q} should be selected so that during an avalanche, the current through the resistor R_{q}, I_{R}, is significantly less than an avalanche current, i.e. I_{R}<<I_{A}. The avalanche current I_{A} starts discharging the collector-base capacitance C_{CB}, and the collector-base voltage V_{CB} drops steeply. The collector-base voltage V_{CB} drops down to a level slightly below V_{BD}, until the avalanche current I_{A} becomes lower than a self-sustaining level. At this time, the avalanche stops. This process is very rapid due to the avalanching, as illustrated in FIG. 4A at around time to, and the fast response time to injecting an emitter 3 electron is one of the factors along with high amplification which makes the SEBAT 1 circuit 9 suitable for single-photon detection.

Once the avalanche has stopped (or “quenched”), the resistor current I_{R} starts recharging the collector-base voltage V_{CB}, eventually bringing it back to equal to the supply voltage V_{CC}. The approximate threshold V_{T} to generate a further self-sustaining avalanche in response to a further electron injected to the emitter 3 is also indicated on FIG. 4A, and is typically larger than the notional breakdown voltage VBD In the example shown in FIG. 4A, the collector base voltage V_{CB} has recharged sufficiently by time t₁. During the period t₁-t₀, the SEBAT 1 may be unable to response to an electron injected to the emitter 3, so that the recharge time t₁-t₀ should be configured to be as short as possible. The example shown in FIG. 3 uses passive reset (recharging). However, faster recovery may be obtainable, for example using active reset circuits known from SPADs.

When the next electron injected by the emitter 3 reaches the collector-base junction, the same cycle may start again. For example, see times t₂ to t₃ and t₄ to t₅ is illustrated in FIG. 4A.

Each of these cycles result in a negative pulse in the collector-base voltage V_{CB} (see FIG. 4A), which is amplified and inverted by the amplifier 10, for example a simple inverter, to generate square wave output pulses on the output Vₒᵤₜ (see FIG. 4B).

By counting the number and/or rate of pulses in the output Vₒᵤₜ, the emitter current I_{E} may be measured. This is best suited to very low levels of emitter current I_{E}, since as current I_{E} increases, the output signal will saturate at a maximum rate determined by the reset time t₁-t₀≈t₂-t₃≈t₄-t₅.

Further discussion of SEBATs 1 operation may be found in Lany et al, “Electron counting at temperature in an avalanche bipolar transistor” Applied Physics Letters 92, 022111 2008.

There is a non-vanishing probability of an electron injected to the emitter 3 traversing the SEBAT 1 without generating a self-sustaining avalanche. Thus, although often referred to as “single electron”, in the context of a SEBAT, this refers to the fact that a response may be triggered by a single electron, not that every single electron will always generate the avalanche response. In this respect, it is similar to SPADs, which do not necessarily trigger in response to every incident photon.

The description hereinbefore relates to an NPN SEBAT 1, but may be adapted to PNP devices. For example, the polarities of doping may be reversed in the exemplary SEBAT 1 shown in FIGS. 1 and 2 to product an equivalent PNP SEBAT device (not shown).

### Short-Wave Infrared (SWIR) Photodetector

Silicon SPADs have good performance at visible wavelengths or shorter. However, due to the bandgap of silicon, silicon SPADs have reduced sensitivity above 900 nm, cutting off entirely between about 1,000 and 1,100 nm.

Other semiconductors could be considered for operation as SPADs to extend sensitivity to longer operating wavelengths. For example, Germanium has a smaller bandgap than silicon, at 0.67 eV. However, under the high reverse bias required for SPAD operation, a Germanium SPAD may exhibit unacceptably high dark count rates. Alternatively, organic semiconductors could be considered. However, even with quenching of each avalanche, organic materials would be expected to undergo rapid degradation, even for materials which are operable in a Geiger mode.

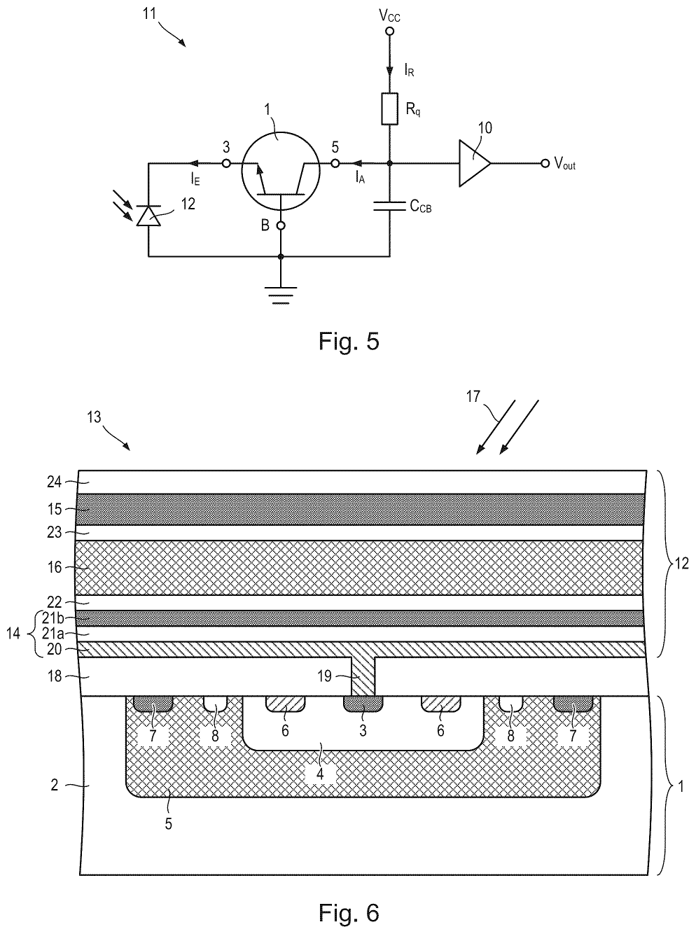

Referring also to FIG. 5, a second circuit 11 is schematically shown.

The second circuit 11 is the same as the circuit 9, with the addition that the emitter 3 of the SEBAT 1 is coupled directly to receive photoelectrons generated in a thin film photodiode 12. The photodiode 12 is sensitive to wavelengths of 900 nm and above. Using the SEBAT 1 to trigger avalanche multiplication in response to potentially as few as a single electron injected from the photodiode 12 allows combining the performance of silicon avalanching with expanded wavelength ranges available using different active materials for the photodiode 12. The photodiode 12 operates at zero bias, or at a low reverse bias to enhance sensitivity, reducing dark currents in the photodiode 12. Additionally, active materials of the photodiode 12 do not experience avalanching by impact ionisation, enabling use of a wider range of materials including, but not limited to, organic semiconductors, quantum dots, and so forth.

US 2019/0131467 A1 describes connecting a germanium photodiode in parallel with the emitter of a single electron bipolar avalanche transistor (SEBAT). The drawbacks of this approach include that fabrication of a germanium photodiode is not directly compatible with standard silicon CMOS fabrication techniques, and that even at zero-bias Germanium photodiodes may still exhibit relatively high dark currents unless cooled.

The inventors propose herein monolithically integrated thin-film photodiodes 12, fabricated directly in contact with emitters 3 of silicon SEBATs 1.

Referring also to FIG. 6, a schematic cross-section of a SWIR photodetector 13 is shown.

The SWIR photodetector 13 includes a SEBAT 1 having an emitter 3, a base 4 and a collector 5. For example, the SEBAT 1 may be the exemplary SEBAT 1 shown in FIG. 1. However, the precise structure of the SEBAT 1 is not critical, provided that the emitter 3 thereof is available and exposed for deposition of the photodiode 12. The SEBAT 1 should also be formed using CMOS compatible materials and processes, for example a CMOS compatible silicon Si substrate 2. Metallisations contacting the base 4 and collector 5 are omitted from FIG. 6 for clarity of the illustration.

The thin-film photodiode 12 includes a cathode 14 and an anode 15, with a photoactive layer 16 disposed between the cathode 14 and anode 15. The photodiode is formed directly on the SEBAT 1 and configured such that, if the SEBAT is NPN, the cathode 14 of the photodiode directly contacts the emitter 3. Alternatively, if the SEBAT is PNP, the photodiode 12 structure should be reversed (about the thickness direction) such that the anode 15 of the photodiode 12 directly contacts the emitter 3 instead. The SWIR photodetector 13 is adapted to respond to incident light 17 having a wavelength exceeding 900 nm through selection of the material(s) for the photoactive layer 16. In some examples, materials for the photoactive layer 16 may be selected so that sensitivity of the photodiode 12 has a peak at a wavelength greater than or equal to 1100 nm, for example between 1110 nm and 1600 nm.

For LiDAR applications, detection wavelengths should be chosen based on the operating wavelength of the laser to be used. Examples of laser wavelengths available in the appropriate range include (without being limited to) 905 nm, 1064 nm, 1310 nm, 1380 nm, 1550 nm and so forth. For such LiDAR applications, the materials for the photoactive layer 16 may be selected so that sensitivity of the photodiode 12 has a peak at, or close to (for example ±15 nm) the operating wavelength of the laser. A dual peak sensitivity may be obtained by, for example, blending several organic semiconductors to form the photoactive material layer.

When describing the thin-film photodiode 12, the term “thin-film” means that the light absorbing layer part of the photodiode 12 does not exceed a thickness of 1000 nm. The photodiode 12 is deposited using one, or a combination, of thin-film deposition processes including, but not limited to, evaporation, vacuum deposition, solution processing such as spin coating or printing, molecular self-assembly, and so forth.

In the example shown in FIG. 6, an insulating layer 18 overlies the SEBAT 1. The insulating layer 18 prevents the cathode 14 (or anode 15 when the SEBAT is PNP) from shorting the metallisations connecting to the base 4 and in particular the collector 5. The insulating layer 18 should be thick enough to avoid breakdown between the collector 5 and the cathode 14. A portion of the cathode 14 (or anode 15 for PNP configurations) 3 extends through a via 19 in the insulating layer 18 to make direct contact with the emitter 3.

In some examples the cathode (or anode for PNP configurations) contacting the emitter 3 may include, or take the form of, a CMOS compatible metal such as, for example, aluminium Al, tungsten W, copper Cu, chromium Cr, titanium Ti, titanium nitride TiN, aluminium-titanium nitride AlTiN, tantalum Ta, and alloys thereof, and metal silicides such as WSi₂. TiSi₂, CoSi₂, MoSi₂, TaSi₂. In other examples, the cathode (or anode for PNP configurations) contacting the emitter 3 may include, or take the form of, a conductive oxide such as, for example, indium tin oxide ITO, indium zinc oxide IZO, aluminum doped zinc oxide (AZO), indium gallium zinc oxide (IGZO), or a blend thereof. In still other examples, the cathode (or anode for PNP configurations) contacting the emitter 3 may include, or take the form of, an organic conductor or semiconductor such as, for example, small molecules, polymers, or a blend of one or more of each.

The anode 15 (or cathode 14 for a PNP configuration) should be transparent, for example formed from indium tin oxide ITO, indium zinc oxide IZO, or a blend thereof. In other examples, the transparent anode 15 (or transparent cathode 14 for a PNP configuration) may be formed from conductive polymer(s).

In some examples, the cathode 14 (or anode 15 in a PNP configuration) may be a single layer. However, in other examples such as the detector 13 shown in FIG. 6, the cathode 14 (or anode 15 in a PNP configuration) takes the form of a multilayer formed from a first CMOS compatible metal layer 20 directly contacting the emitter 3, and one or more intermediate layers 21 supported on the CMOS compatible metal layer 20. Each intermediate layer 21 may be conductive, or may be semiconductive. A selection of suitable CMOS compatible metals have been described hereinbefore. Either or both of the cathode 14 and anode 15 may include one or more intermediate layers 21. The example shown in FIG. 6 includes a pair of intermediate layers 21a, 21b in the cathode 14. One or more intermediate layers 21 will be included when needed to obtain better work-function matching to the photoactive layer, so as to avoid creating any potential barriers which may impede transfer of an electron from the photodiode 12 into the emitter 3. In practice, the number of intermediate layers should be kept to a minimum as each interface may increase a chance of unwanted trap states. Each intermediate layer 21 may include, or take the form of, a second CMOS compatible metal different from the first CMOS compatible metal layer 20, a conductive oxide, an organic conductor, or an organic semiconductor, with options for each material type as described elsewhere herein.

Optionally, and in particular when the photoactive layer 16 comprises organic semiconductor(s), the photodiode 12 may additionally include an electron transport (or hole blocking) layer 22 between the cathode 14 and the photoactive layer 16, and/or a hole transport (or electron blocking) layer 23 between the anode 15 and the photoactive layer 16. Optionally, and in particular when the photoactive layer 16 comprises organic semiconductor(s), the photodiode 12 may be environmentally sealed using a sealing/capping layer 24 formed using materials known from organic light emitting diodes, organic photodiodes and similar organic semiconducting devices.

The SWIR photodetector 13, including the integrally formed SEBAT 1 and thin-film photodiode 12, is connected to a quenching circuit for the SEBAT 1, and an amplifier 10 is coupled to the collector 5 to convert output current spikes to digital pulses (see FIGS. 4A and 4B). For example, the second circuit 11 shown in FIG. 5 may be used. In general, any combination of quenching circuit, reset circuit and/or output processing known for use with for SPADs may be used with a SWIR photodetector according to the present specification. For example, the SEBAT 1 of the SWIR photodetector 13 may be configured for any combination of passive or active quenching and passive or active reset.

The implementation of the SEBAT 1 of the SWIR photodetector 13 using CMOS materials and processes enables ready integration of the quenching circuit and/or the amplifier 10 for the SEBAT 1 on the same substrate 2 as the SEBAT 1.

The photodiode 12 of the SWIR photodetector 13 may be configured for zero-bias operation and/or reverse bias operation. The configuration of the photodiode 12 for reverse-bias operation, when included, takes the form of including contacts enabling application of a reverse-bias across the photodiode 12. Improved sensitivity to incident light 17 obtainable by reverse bias operation needs to be balanced against any associated increase in dark current, for example to maintain a dark-current of the photodiode below a dark-current threshold (either in absolute current or current per unit area). The reverse bias is preferably low, for example less than a breakdown voltage of the photodiode 12, and preferably less than the supply voltage V_{CC}. A low reverse bias may be less than or equal to standard potentials used in transistor-transistor-logic (TTL) circuits. Preferably, a reverse bias applied to the photodiode 12 has a magnitude of 0.5 V or less.

In this way, a SEBAT 1 may be connected directly to, and monolithically integrated with, a thin-film photodiode 12 such that a charge carrier generated from as few as a single photon absorbed in the photodiode 12 may be detected by triggering an avalanche effect in the SEBAT 1 to generate a macroscopic measurable output Vₒᵤₜ. This avalanche is self-quenching (analogous to SPAD devices) such that the current is lowered, and the avalanche stopped, allowing the SWIR photodetector 13 to recharge ready to receive the next photoelectron. The monolithic integration of the SEBAT 1 and photodiode 12 create a benefit above what each technology can achieve independently, in particular by coupling the carrier multiplication of silicon and versatility of CMOS processing with the extension of sensitivity to longer wavelengths afforded by a non-silicon photodiode. Unlike previous proposals such as the germanium photodiode of US 2019/0131467 A1, photodiodes 12 proposed herein use thin-film processing techniques compatible with direct deposition onto the SEBAT 1, within (or following directly on from) CMOS processing.

The possible applications of the SWIR photodetector 13 for LiDAR have already been mentioned. However, the SWIR photodetector 13 may be applicable to a wide range of SWIR sensing applications. For example, security and surveillance, augmented/virtual reality (AR/VR), medical, driver assistance & autonomous vehicles, industrial automation, hyperspectral imaging, and so forth.

### Example 1—Organic Photodiode

In one preferred example, the photoactive layer 16 of the photodiode 12 is formed from one or more organic semiconductors. The organic semiconductor(s) may take the form of small molecule organic semiconductors, polymer semiconductors, or a blend thereof.

A preferred photodiode structure is:

Cathode/Photoactive Layer/Anode in which Cathode is a layer of indium-tin oxide (ITO) of about 30-100 nm thickness in which the surface of the ITO is treated with polyethyleneimine (PETE) to modify the work function of the ITO; the photoactive layer is a bulk heterojunction layer of about 300-600 nm thickness comprising an electron-donating material and an electron-accepting material; and Anode is a stack of MoO₃ of about 5-20 nm thickness and ITO of about 30-100 nm thickness.

A preferred electron-donating material is a donor-acceptor (DA) polymer, for example:

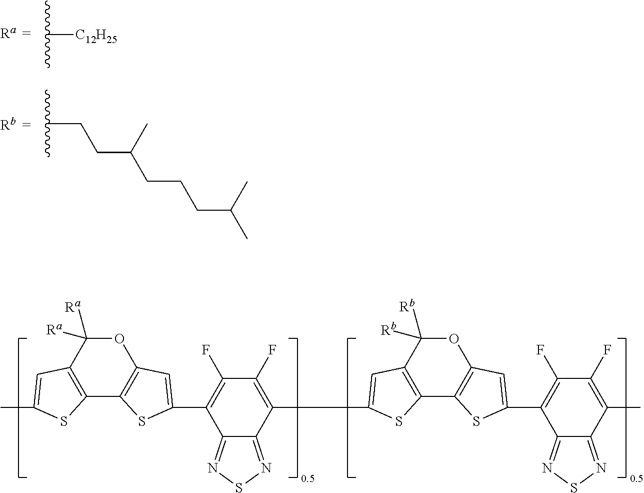

Preferred electron-accepting materials are selected from non-fullerene acceptors of formula ADA or ADA′DA wherein A is a monovalent electron-accepting unit; D is a divalent electron-donating unit; and A′ is a divalent electron-accepting unit, wherein each A may be directly bound to D or spaced apart therefrom by a bridging unit, for example thiophene. Exemplary compounds of formula ADA are the following compounds disclosed in WO22/129137, the contents of which are incorporated herein by reference:

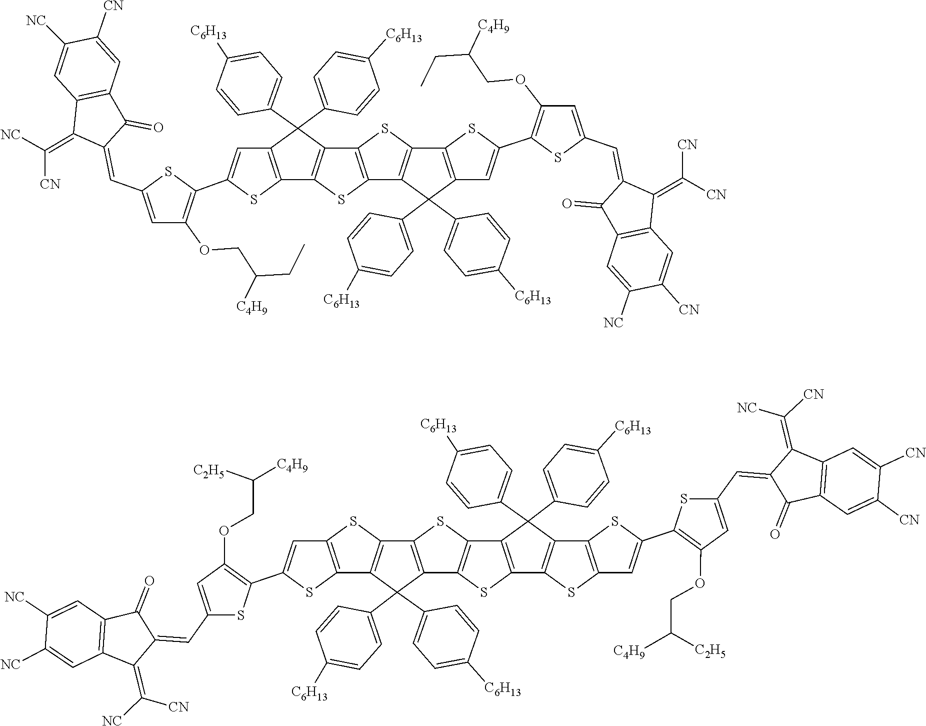

Exemplary compound of formula ADA′DA include:

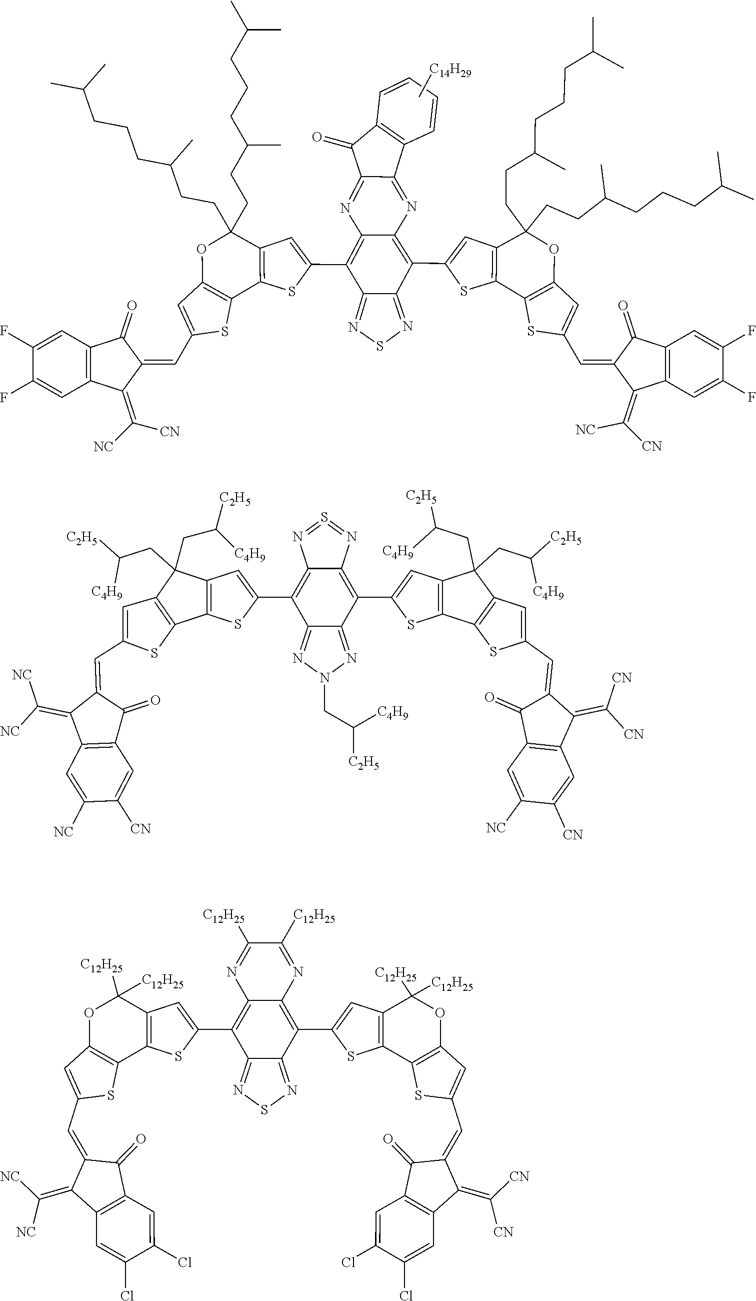

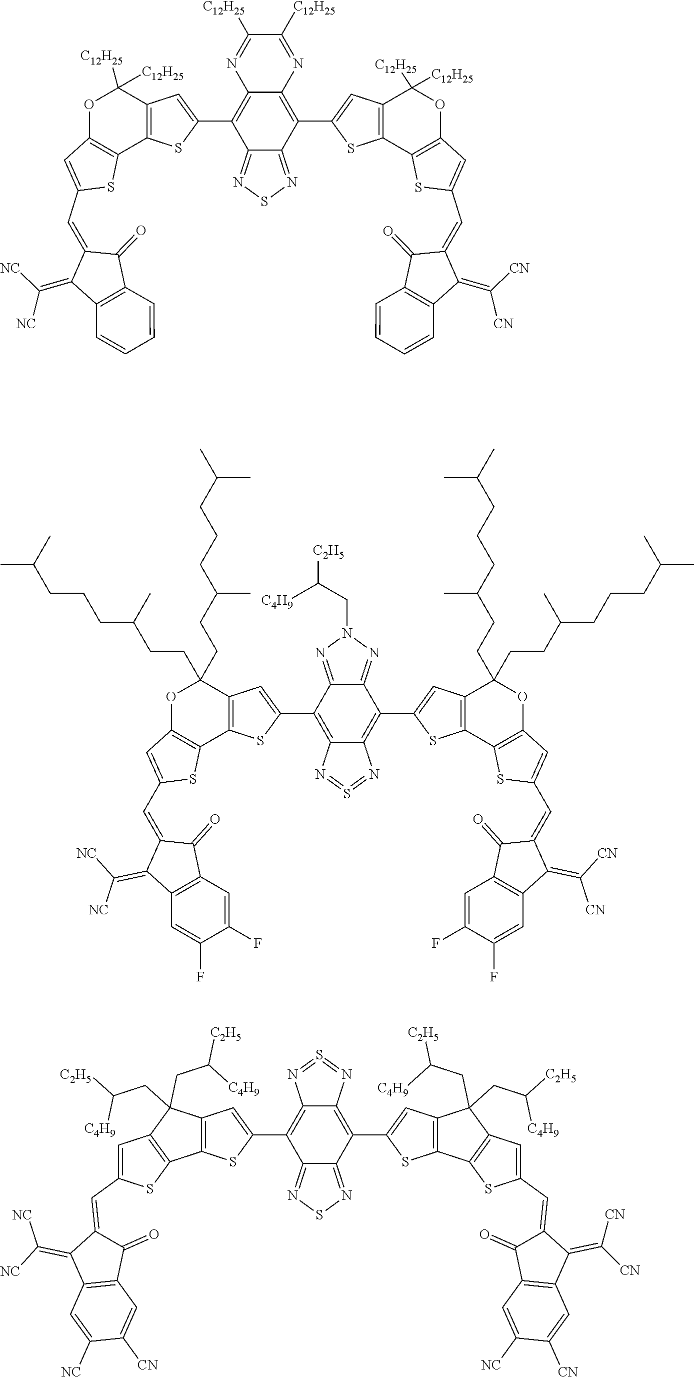

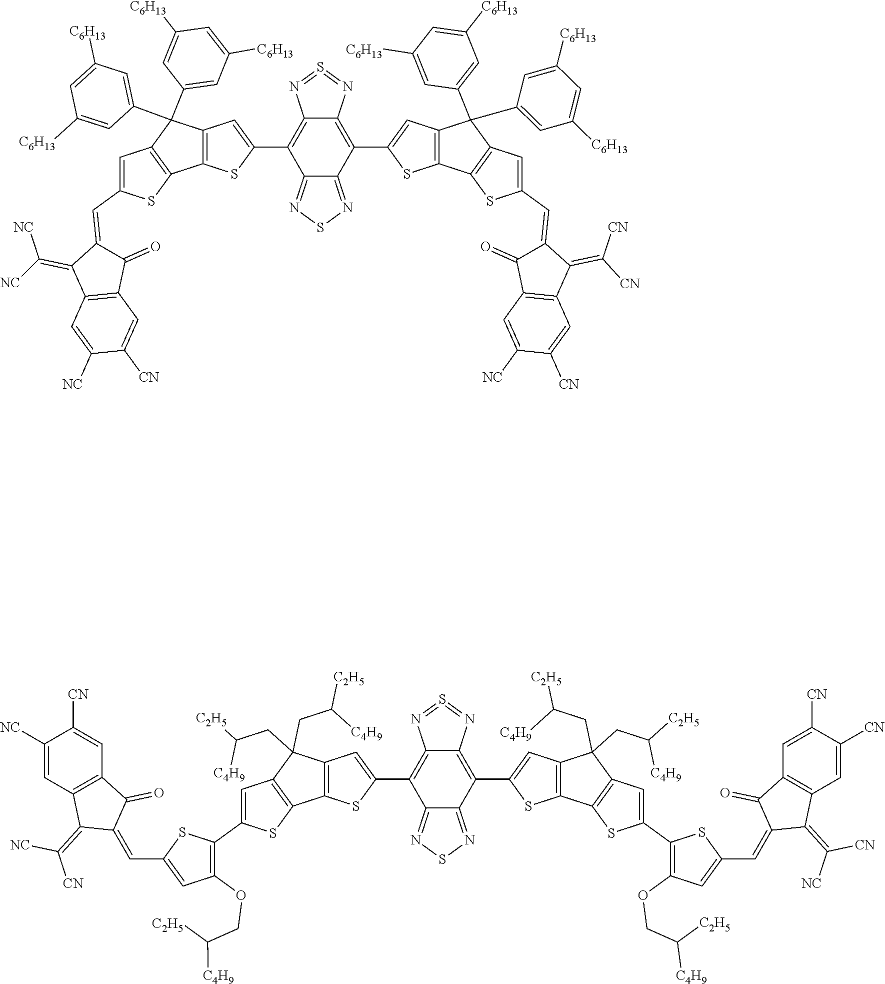

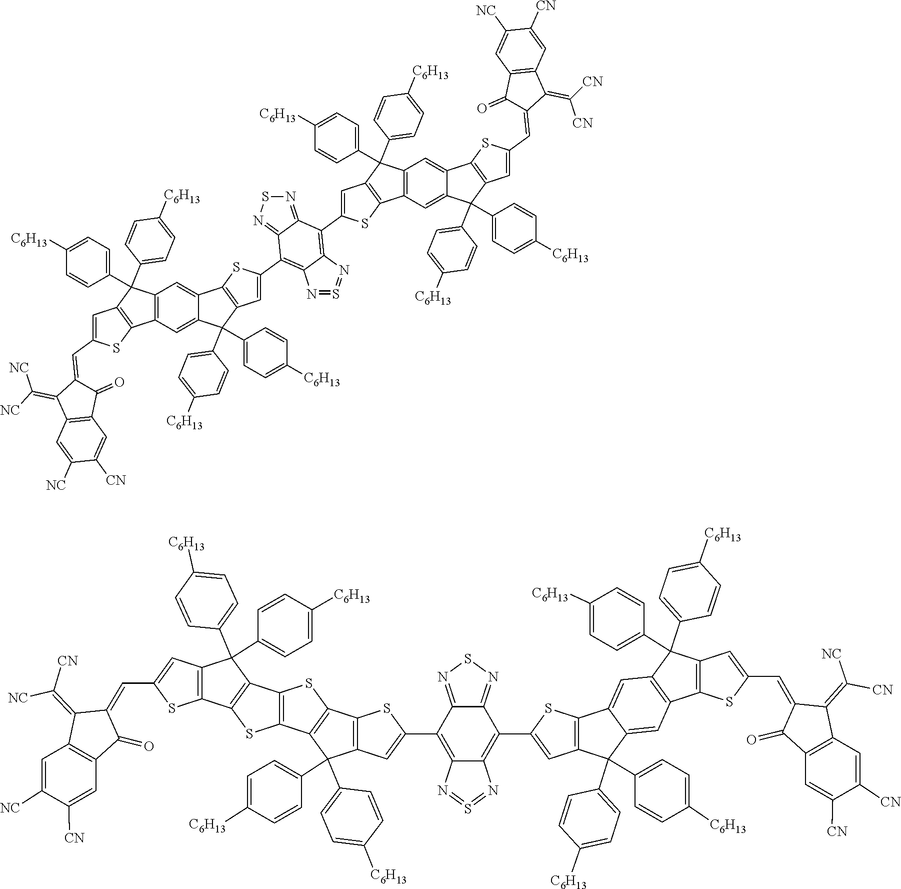

An exemplary method for forming ADA′DA compounds is:

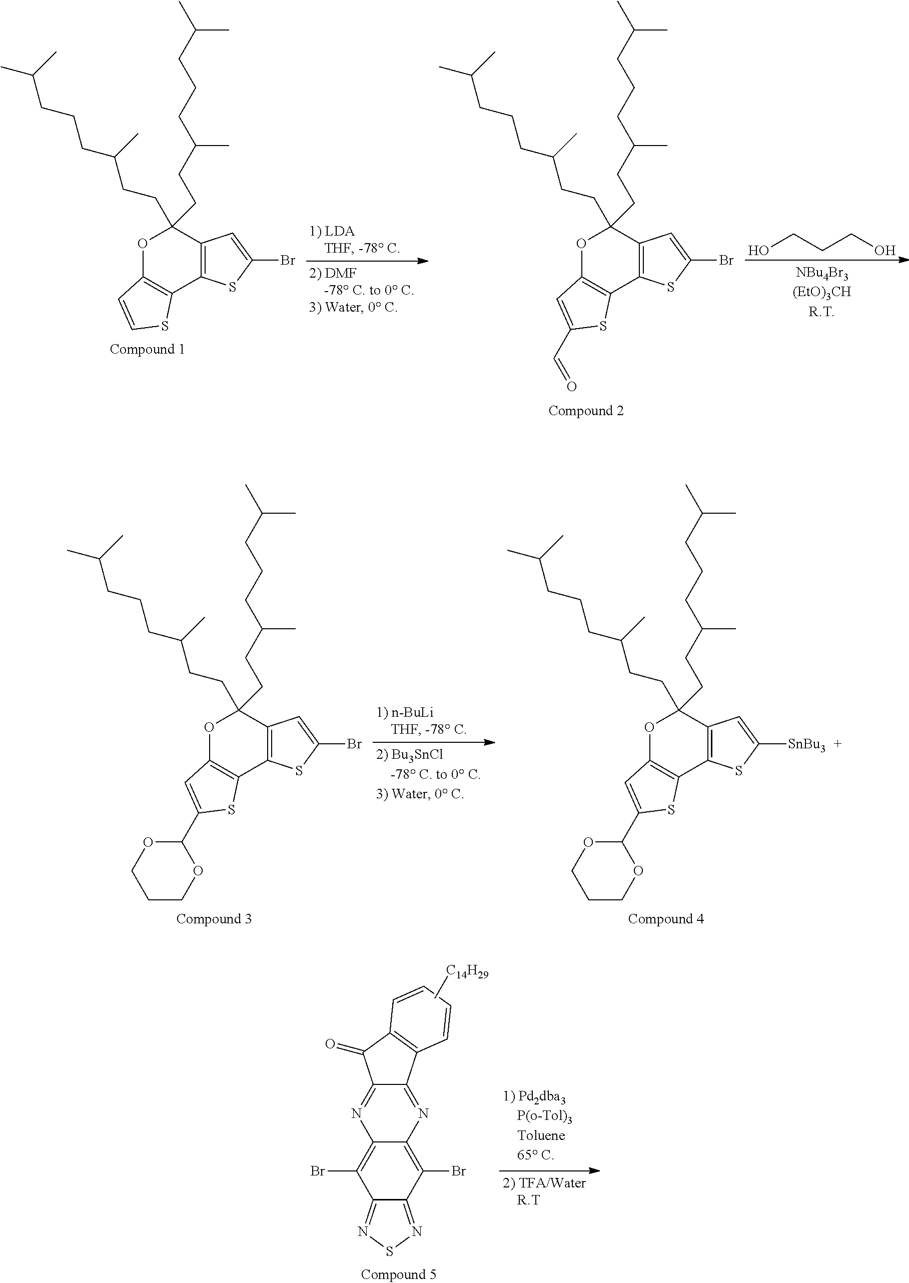

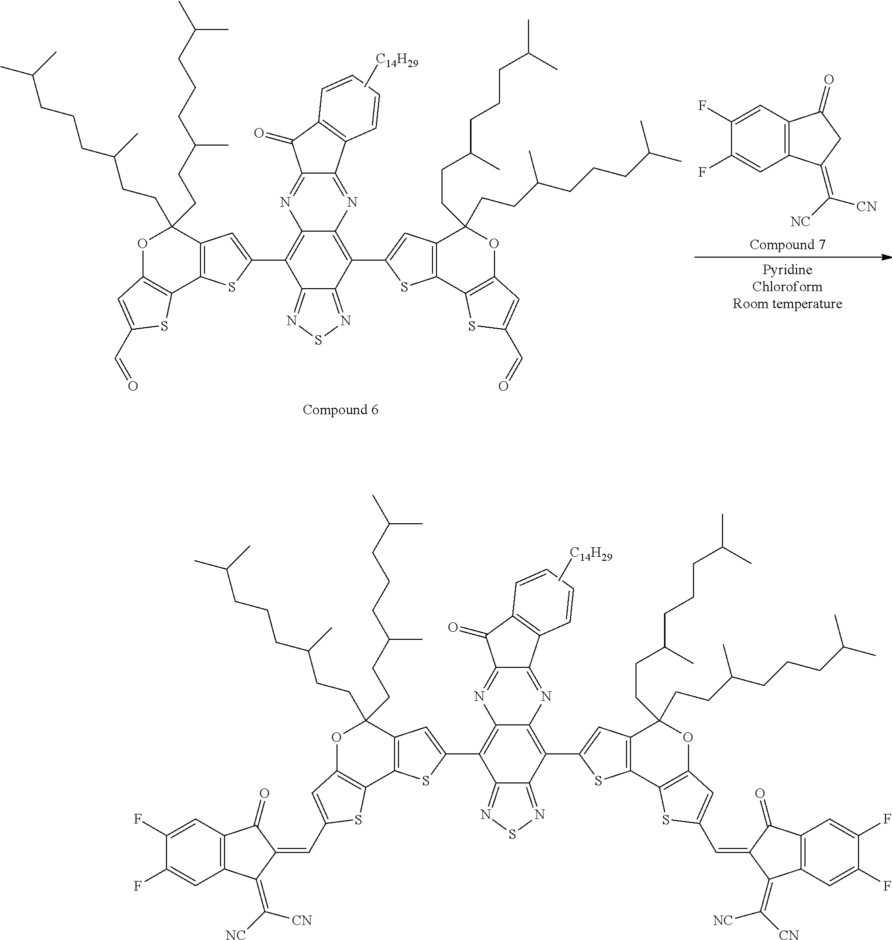

The bulk heterojunction layer may consist of a single electron-donating material and a single electron-accepting material or it may comprise one or more further materials. In a preferred embodiment, the bulk heterojunction layer comprises an electron-donating material, a non-fullerene acceptor and a fullerene acceptor.

### Example 2—Quantum Dot Photodiode

In another example, a photoactive layer 16 of the photodiode 12 includes quantum dots. For example, quantum dots providing the photoactive layer 16 may take the form of colloidal nano-crystals.

### Example 3—Perovskite Photodiode

In a still further example, a photoactive layer 16 of the photodiode 12 includes, or is formed from, perovskite material. For example, the perovskite material may include CH₃NH₃PbI₃₋ₓClₓ.

### First SWIR Photodetector Array

The use of CMOS compatible materials and processes to form the SWIR photodetector 13, and the ready integration of related elements such as quenching circuits (e.g. quench resistor R_{q}) and/or amplifiers 10, opens up the possibility to fabricate an arrangement of SWIR photodetectors 13 on a single substrate 2 (more preferably a large number of such arrays per substrate). Such an array may be one dimensional, or more preferably two-dimensional. The arrangement of SWIR photodetectors 13 in a two-dimensional array may be according to any one of the available two-dimensional Bravais lattices. Due to the circular shapes preferably used for SEBATs 1 to avoid electric field concentrations (see FIG. 2), a close-packed lattice may be preferable when it is desired to maximise areal density of SWIR photodetectors 13.

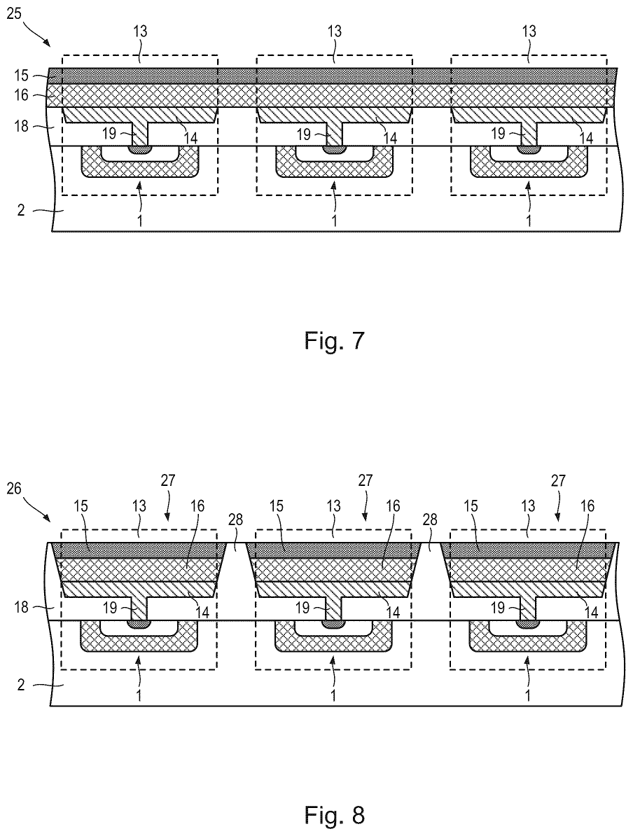

Referring also to FIG. 7, a portion of a first detector array 25 is shown in schematic cross-section.

Each SWIR photodetector 13 of the first detector array 25 has the same structure as a the SWIR photodetector 13 described hereinbefore and illustrated in FIG. 6 (or any modification thereof described herein), except that layers of the photodiode 12 other than the cathode 14 (or anode 15 for a PNP configuration) are uniform and extend across the array 25. This structure is expected to simplify fabrication since patterned layers are typically more complex and time consuming to form. For example, in the case of an organic photodiode (OPD), the SEBATs 1, insulating layer 18 and cathodes 14 (or anodes 15 for a PNP configuration) may be prepared using CMOS processing, followed by direct deposition of the photoactive layer 16 (and any of the optional intermediate layers such as an electron/hole transport layer 22, 23 etc) without any need for patterning. For example, organic layers may be spin coated over a processed substrate 2 bearing SEBATs 1 and cathodes 14.

This structure is possible because the photodiode 12 structures are very thin, with photoactive layers less than 1000 nm thick, compared to lateral spacings of at least several microns due to the wavelengths of incident light 17 which are of interest. This geometry makes cross-talk at low photocurrent levels unlikely—the outputs Vₒᵤₜ of each SWIR photodetector 13 would likely saturate as described hereinbefore at photocurrents significantly below a level where detectable cross-talk between adjacent SWIR photodetectors 13 would be expected to be problematic.

Although not shown in FIG. 7, the first detector array 25 may include any of the optional features described hereinbefore in relation to the SWIR photodetector 13. When the cathodes 14 are multi-layer, at least the first CMOS compatible metal layer 20 is patterned. If included, the intermediate layers 21 may be patterned or unpatterned, because as already described the geometry of the first detector array 25 will cause vertical conduction to dominate over lateral conduction.

### Second SWIR Photodetector Array

Although layers of the photodiode 12 may be deposited uniformly over an array of SEBATs 1, in some examples it may be desirable to pattern a separate photodiode 12 to correspond to the emitter 3 of each SEBAT 1.

Referring also to FIG. 8 a portion of a second detector array 26 is shown in schematic cross-section.

The second detector array 26 is the same as the first detector array 25, except that the layers for each photodiode 12 are patterned, received within troughs 27 defined by banks 28 extending upwards from the insulating layer 18. The banks 28 may be formed as integral extensions of the insulating layer 18. For example, the troughs 27 may be etched alongside, or immediately before/after, the vias 19. Alternatively, the banks 28 may be deposited after the cathode 14 (or at least first CMOS compatible metal layer 20) deposition and patterning. For example, the banks 28 may be printed, given that the minimum feature size achievable with ink-jet printing may be only a few times that for typical CMOS processes.

The photoactive layers 16, anodes 15, and any other, optional layers 21, 22, 23 are then deposited between the banks 28 to produce the photodiodes 12. In an example where the photodiodes 12 are OPDs, these may be printed.

Although not shown in FIG. 8, the second detector array 26 may include any of the optional features described hereinbefore in relation to the SWIR photodetector 13.

In further examples, structures intermediate between the first 25 and second 26 detector arrays may be produced. For example, layers 15, 16, 21, 22, 23 above the cathode 14 may be may be a mixture of patterned and unpatterned layers.

In the preceding description, it has been assumed that the SEBATs 1 are produced with a NPN configuration. However, any or all of the preceding examples may be modified for a PNP configuration by reversing the doping of regions forming the SEBAT 1, and by inverting the photodiode 12 structures such that the anode(s) 15 are formed directly on the respective emitter(s) 3.

1. A short-wave near infrared, SWIR, photodetector for wavelengths exceeding 900 nm, comprising:
a silicon single-electron bipolar avalanche transistor, SEBAT, having an emitter, a base and a collector, wherein the SEBAT is formed using CMOS compatible materials and processes;
a thin-film photodiode formed directly on the SEBAT and configured such that:
if the SEBAT is NPN, a cathode of the photodiode directly contacts the emitter; or
if the SEBAT is PNP, an anode of the photodiode directly contacts the emitter.

2. The SWIR photodetector of claim 1, wherein the anode or cathode contacting the emitter comprises a multilayer.

3. The SWIR photodetector of claim 2, wherein the multilayer comprises:
a first CMOS compatible metal layer contacting the emitter; and
one or more intermediate layers supported on the CMOS compatible metal layer.

4. The SWIR photodetector of claim 3, wherein the one or more intermediate layers comprise one or more of:
a second, different CMOS compatible metal;
a conductive oxide;
an organic conductor or an organic semiconductor; and
an organic or inorganic workfunction modification layer.

5. (canceled)

6. (canceled)

7. (canceled)

8. The SWIR photodetector of claim 1, wherein an insulating layer overlies the SEBAT, and wherein the anode or cathode contacting the emitter extends through a via in the insulating layer.

9. The SWIR photodetector of claim 1, further comprising:
a quenching circuit for the SEBAT;
an amplifier coupled to the collector and configured to convert output current spikes to digital pulses.

10. The SWIR photodetector of claim 9, wherein the quenching circuit and/or the amplifier are integrally formed on the same substrate as the SEBAT.

11. The SWIR photodetector of claim 1, wherein the photodiode is configured for zero-bias operation.

12. The SWIR photodetector of claim 1, wherein the photodiode is configured for reverse-bias operation.

13. The SWIR photodetector of claim 1, wherein the sensitivity of the photodiode has a peak at a wavelength greater than or equal to 1100 nm.

14. The SWIR photodetector of claim 1, wherein a photoactive layer of the photodiode comprises quantum dots.

15. The SWIR photodetector of claim 1, wherein a photoactive layer of the photodiode comprises a perovskite material.

16. The SWIR photodetector of claim 1, wherein a photoactive layer of the photodiode comprises one or more organic semiconductors.

17. The SWIR photodetector of claim 1, wherein a photoactive layer of the photodiode does not include Germanium.

18. A SWIR photodetector array comprising:
a plurality of SWIR photodetectors according to claim 1, arranged in an array.

19. The SWIR photodetector array of claim 18, wherein one or more layers of the photodiode other than the anode or cathode contacting the emitter are uniform and extend across the array; or wherein a separate photodiode is formed to correspond to each emitter.

20. (canceled)

21. The SWIR photodetector array of claim 18, wherein the array is one-dimensional.

22. The SWIR photodetector array of claim 18, wherein the array is two-dimensional.

23. A light detection and ranging, LIDAR, system comprising the SWIR photodetector according to claim 1.

24. A method of fabricating a short-wave near infrared, SWIR, photodetector for wavelengths exceeding 900 nm, comprising:
depositing a thin-film, vertical photodiode directly on a silicon single-electron bipolar avalanche transistor, SEBAT, having an emitter, a base and a collector, wherein the SEBAT is formed using CMOS compatible materials and processes;
wherein if the SEBAT is NPN, a cathode of the photodiode is directly deposited on the emitter, or if the SEBAT is PNP, an anode of the photodiode is directly deposited on the emitter.
